(19) United States
(12) Patent Application Publication
(10) Pub. No.: US 2025/0210367 A1
(43) Pub. Date: Jun. 26, 2025

(54) ATOMIC LAYER ETCHING OF SILICON OXIDE AT CRYOGENIC TEMPERATURE

(71) Applicant: Applied Materials, Inc., Santa Clara, CA (US)

(72) Inventors: Sonam Dorje SHERPA, Santa Clara, CA (US); Mir ABDULLA AL GALIB, Santa Clara, CA (US); Alok RANJAN, Santa Clara, CA (US)

(21) Appl. No.: 18/392,785

(22) Filed: Dec. 21, 2023

(51) Int. Cl. H01L 21/311; H01J 37/32; H01L 21/308

(52) U.S. Cl. CPC H01L 21/31116; H01J 37/321; H01J 37/32449; H01J 37/32724; H01J 37/32816; H01L 21/3081; H01J 2237/3341; H01J 2237/3346

(57) ABSTRACT

Embodiments of the disclosure include a method for forming a feature on a substrate includes exposing a portion of a silicon containing layer formed over the substrate through an opening formed though a masking layer to a carbon-free fluorine containing gas to convert the exposed portion of the silicon containing layer to a reactive portion, and etching the reactive portion by exposing the reactive portion of the silicon containing layer to a plasma formed from an inert gas.

### BACKGROUND

### Field

Embodiments of the present invention generally relate to semiconductor manufacturing, in particular, embodiments herein relate to a method for atomic layer etching (ALE) of a semiconductor device at a cryogenic temperature.

### Description of the Related Art

Atomic layer etching (ALE) is a technique used in semiconductor manufacturing that includes a sequence of steps that alternate between causing a chemical reaction on a portion of a top atomic layer of a substrate stack and an etching step where only the chemically modified portions of the top atomic layer are removed. Conventionally, ALE process use greenhouse gases that deposit a fluorocarbon film on the surface of the top atomic layer. The fluorocarbon film results in a polymer that is deposited on the surface of the top atomic layer. The use of the polymerizing gases introduce trade-offs such as iso-dense loading and corner residues due to the inaccessibility to corners of high-aspect ratio structures. Conventional ALE and etch techniques require additional steps to reduce the corner residues on high-aspect ratio structures. These steps may include an overetch or a declog step to reduce the clogging at the opening of the high aspect ratio structures.

### SUMMARY

In an embodiment a method for forming a feature on a substrate includes exposing a portion of a silicon containing layer formed over the substrate through an opening formed though a masking layer to a carbon-free fluorine containing gas to convert the exposed portion of the silicon containing layer to a reactive portion, and etching the reactive portion by exposing the reactive portion of the silicon containing layer to a plasma formed from an inert gas.

In another embodiment a method for forming a feature on a substrate includes exposing a portion of a silicon containing layer formed over the substrate through a masking layer formed over the silicon containing layer to hydrogen fluoride (HF) vapor to convert the exposed portion of the silicon containing layer to a reactive portion, and etching the reactive portion by exposing the reactive portion of the silicon containing layer to a plasma formed from argon (Ar).

In another embodiment a processing chamber includes a controller, and a memory for storing instructions, which, when executed by the controller, causes the controller to perform a method for forming a feature on a substrate comprising. The method includes exposing a portion of a silicon containing layer formed over the substrate through an opening formed though a masking layer to a carbon-free fluorine containing gas to convert the exposed portion of the silicon containing layer to a reactive portion, and etching the reactive portion by exposing the reactive portion of the silicon containing layer to a plasma formed from an inert gas.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional side view of a process chamber, according to embodiments of the present disclosure.

FIGS. 2A-2F illustrate cross-sectional views following a series of operations of an atomic layer etching (ALE) process according to embodiments of the present disclosure.

FIG. 3 illustrates a flow diagram of a method for an atomic layer etching (ALE) process shown in FIGS. 2A-2F according to embodiments of the present disclosure

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Conventional, atomic layer etching (ALE) process use greenhouse gases that deposit a fluorocarbon film on the surface of an top atomic layer. The fluorocarbon film results in a polymer that is deposited on the surface being etched. Conventional ALE and etch techniques require additional steps to reduce the corner residues on high-aspect ratio structures. These steps may include an overetch or a declog step to reduce the clogging at the opening of the high aspect ratio structures. Thus, conventional ALE processes have room to become more environmentally friendly while also improving etch results.

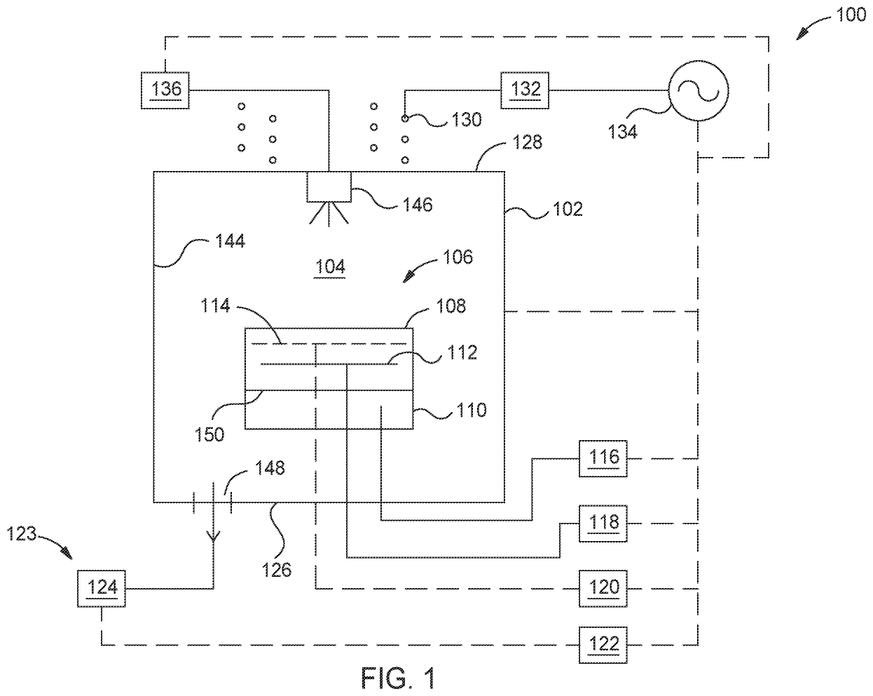

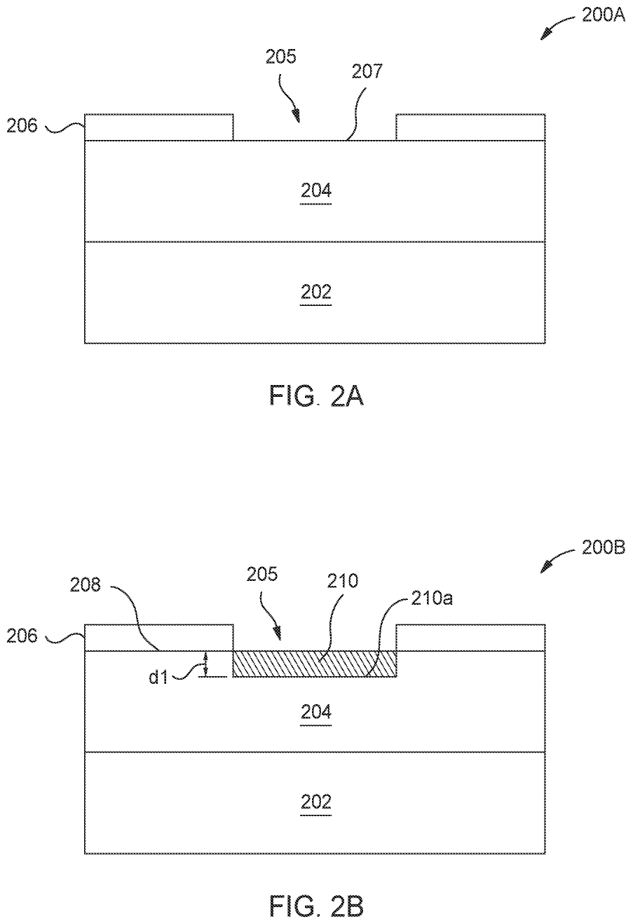

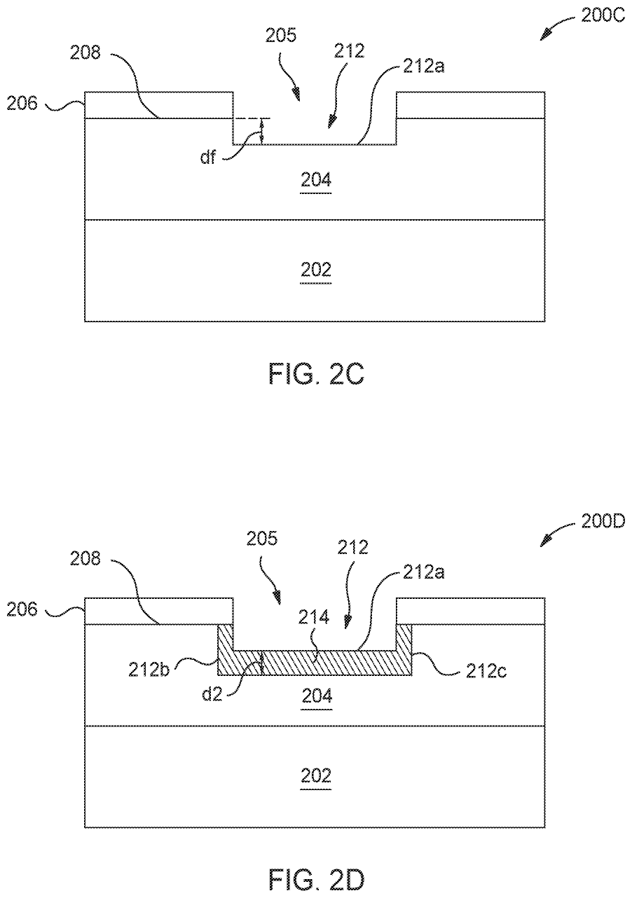

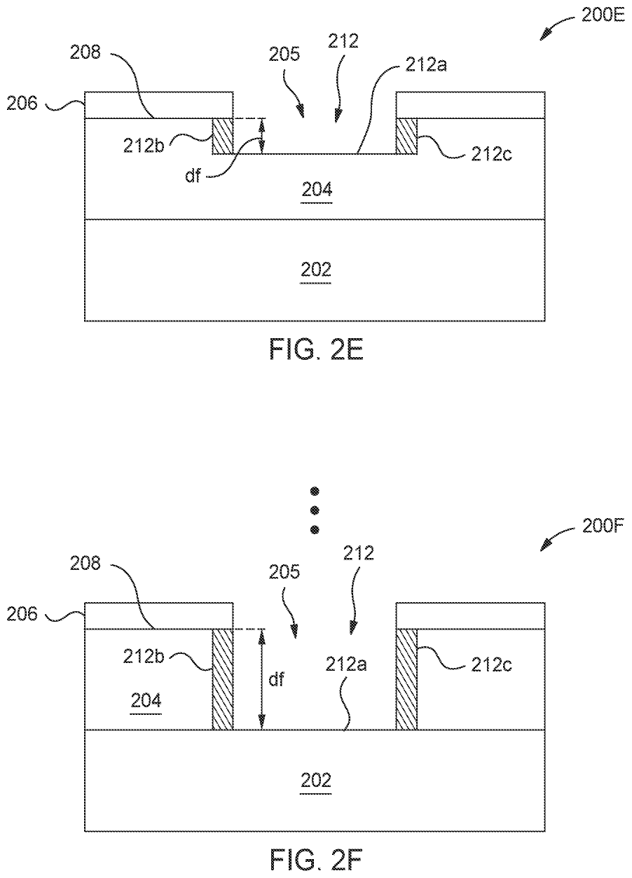

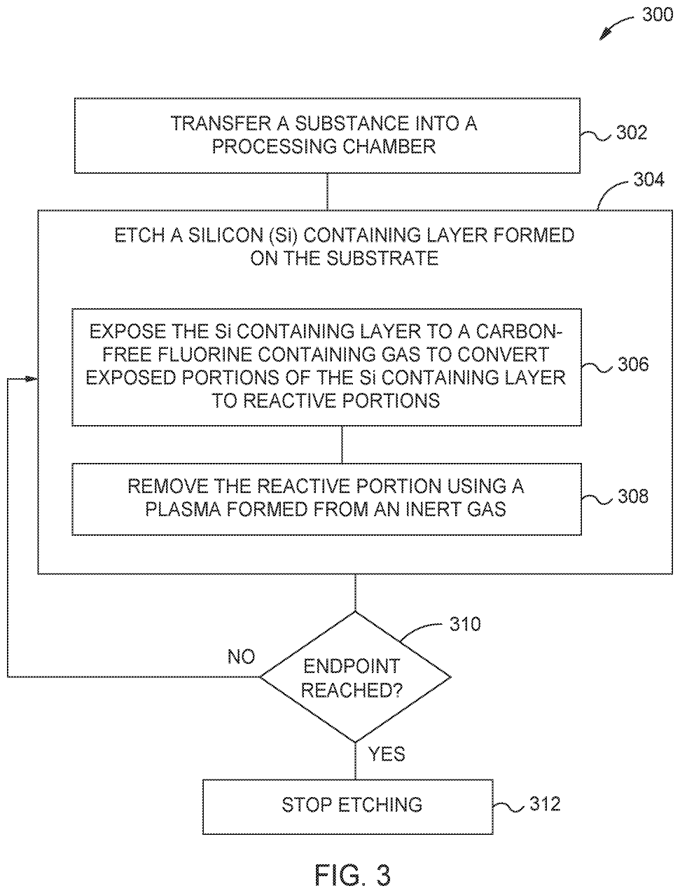

Embodiments described herein disclosed an atomic layer etching (ALE) process that cause a chemical reaction of a top atomic layer of semiconductor device using carbon-free fluorine containing gas. Advantageously, the use of the carbon-free fluorine containing gas is environmentally safe because it is not a greenhouse gas. Additionally, the use of the carbon-free fluorine gas does not cause a polymer layer to be deposited on the surface of the top atomic layer. Furthermore, the use of the carbon-free fluorine containing gas does not require additional steps of an overetch or a declog step to reduce the clogging at the opening of the high aspect ratio structures. FIG. 1 is a cross-sectional schematic view of an exemplary plasma processing chamber 100, shown configured as an etch chamber, having a substrate support assembly 106. The processing chamber 100 is an example chamber that may be used to perform the method discussed in FIGS. 2 and 3, among other processes. The substrate support assembly 106 may be utilized in other types of plasma processing chambers, for example plasma treatment chambers, annealing chambers, physical vapor deposition chambers, chemical vapor deposition chambers, and ion implantation chambers, among others, as well as other systems where the ability to uniformly maintain a surface or workpiece, such as a substrate, at a cryogenic processing temperature is desirable.

The processing chamber 100 includes a chamber body 102 having chamber sidewalls 144, a chamber bottom 126 and a removably coupled lid 128 that enclose an inner volume 104. The chamber lid 128 is coupled to a gas panel 136 to allow gases to be provided into the inner volume 104 through an injection apparatus 146. In some examples, the gas panel 136 provides purging, cleaning, process, and/or additive gases to the inner volume 104. The chamber lid 128 also supports an RF coil 130. The RF coil 130 is energizable by a RF power supply 134. The RF power supply 134 provides RF power through a RF matching circuit 132 to the RF coil 130. In some examples, the RF matching circuit 132 conditions the RF power to a suitable impedance to improve performance in the RF coil 130. In some examples, the energized RF coil 130 excites the process gases to create a plasma within the inner volume 104. Process gases, along with any processing by-products, are removed from the inner volume 104 through an exhaust port 148 formed in the chamber sidewalls 144 or chamber bottom 126 of the chamber body 102. The exhaust port 148 is coupled to a pumping system 123, which includes throttle valves and pumps (not shown) utilized to control the vacuum levels within the inner volume 104.

The substrate support assembly 106 is disposed within the inner volume 104. The substrate support assembly 106 is configured to receive, support, and process a substrate thereon. In some examples, the substrate support assembly 106 comprises an electrostatic chuck 108 having bottom 150 disposed on a cooling base 110. The electrostatic chuck 108 is configured to generate electrostatic to secure a substrate (not shown) thereon during processing. The electrostatic chuck 108 includes a chucking electrode 114 that is connected to a chucking electrode power supply 120. When energized, the chucking electrode 114 generates the electrostatic force that secures the substrate to the electrostatic chuck. The cooling base 110 is configured to remove thermal energy from the substrate support assembly 106. In some examples, the processing chamber 100 may be a cryogenic enabled chamber wherein the cooling base 110 is configured to reduce the temperature of the substrate support assembly 106 to less than 0 degrees Celsius. The temperature of the cooling base 110 is regulated by flowing a temperature regulating fluid therethrough. The cooling base 110 is coupled to a heat exchanger 116 to control the temperature of the temperature regulating fluid.

In some examples, the substrate support assembly 106 may include a heater 112. The heater 112 may be disposed in the electrostatic chuck 108 or other component of the substrate support assembly 106. The heater 112 is used to control the temperature of the substrate support assembly. In one example, the heater 112 is a resistive heating element coupled to a heater power supply 118. Power provided by the heater power supply 118 to the heater 112 is used to help regulate the temperature of the substrate support assembly 106 in concert with the cooling base 110.

A controller 122 is coupled to the processing chamber 100. The controller 122 is utilized to control the functionality of the processing chamber 100, including substrate processing and chamber cleaning operations. The controller 122 is also configured to receive data or input from sensor readings from a plurality of sensors and send or output instructions to various process chamber components or equipment. The controller 122 is equipped with or in communication with a system model (not shown) of the processing chamber 100. The system model is a program configured to estimate parameters (such as a gas flow rate, a gas pressure, a processing temperature, a rotational position of component(s), a heating profile, and/or a cleaning condition) within the processing chamber 100 throughout a processing operations and/or a cleaning operation. The controller 122 is further configured to store readings and calculations. The readings and calculations include previous sensor readings, such as any previous sensor readings within the processing chamber 100. The readings and calculations further include the stored calculated values from after the sensor readings are measured by the controller 190 and run through the system model. Therefore, the controller 122 is configured to both retrieve stored readings and calculations as well as save readings and calculations for future use. Maintaining previous readings and calculations enables the controller 190 to adjust the system model over time to reflect a more accurate version of the processing chamber 100.

The controller 122 can monitor, estimate an optimized parameter, adjust an initiated operation, generate an alert on a display, halt an operation, initiate a chamber downtime period, delay a subsequent iteration of an operation, initiate a cleaning operation, halt a cleaning operation, adjust a heating power, and/or otherwise adjust the process recipe.

The controller 122 includes a central processing unit (CPU) 142 (e.g., a processor), a memory 138 containing instructions, and support circuits 140 for the CPU 142. The controller 190 controls various items directly, or via other computers and/or controllers. In one or more examples, the controller 122 is communicatively coupled to and controls the operation of at least the heat exchanger 116, the heater power supply 118, the chucking electrode power supply 120, the RF power supply 134, the gas panel 136, the vacuum pump 124, and auxiliary chamber components (not shown) within the chamber body 102.

FIGS. 2A-2F illustrate cross-sectional views of a film stack 200A-200F during various stages of an atomic layer etching (ALE) process 300 illustrated in the block diagram of FIG. 3. The following description refers simultaneously to both the ALE process 300 and the sectional views of FIGS. 2A-2F.

The ALE process 300 begins at operation 302 by transferring a substrate 202 having a film stack 200A disposed thereon into a processing chamber 100 as depicted in FIG. 2A. In one example, the film stack 200A includes a masking layer 206 formed over a silicon containing layer 204. The silicon containing layer 204 is formed on substrate 202. Although the silicon containing layer 204 is described as being disposed on the substrate 202, additional intervening layers may be formed between the substrate 202 and the silicon containing layer 204.

In one example, the masking layer 206 may be a hardmask layer. The hardmask layer may be fabricated from titanium nitride (TiN), tantalum nitride (TaN), silicon nitride (SiN), silicon or the like. Alternatively, the masking layer 206 may be a patterned resist layer or a carbon containing layer. The masking layer 206 is patterned with at least one opening 205 that corresponds to desired feature(s) to be etched into the silicon containing layer 204. The masking layer 206 is patterned to expose to-be etched portions of the silicon containing layer 204. In one example, an exposed portion 207 of the silicon containing layer 204 is exposed through the opening 205 formed through the masking layer 206. Although only a single opening 205 is shown through the masking layer 206 in FIG. 2A, it is understood that many additional openings 205 may be formed through the masking layer 206 to expose portions 207 of the silicon containing layer 204.

In one or more examples, the silicon containing layer 204 is a silicon based dielectric material. For example, the silicon containing layer is fabricated from, but is not limited to, silicon oxide (SiO), silicon nitride (SiN), silicon (Si), and combinations thereof. In one or more examples, the substrate may comprise, but is not limited to, silicon germanium (SiGe), gallium arsenide (GaAs), glass, aluminum nitride (AlN), silicon carbide (SiC), or other suitable substrate materials.

At operation 304, the silicon containing layer 204 is etched, as depicted in FIGS. 2B-C. At operation 304, the exposed portion 207 of the silicon containing layer 204 is incrementally etched through the opening 205 of the masking layer 206. In one or more examples, etching the silicon containing layer 204 includes operation 306-308. In one or more examples, during the etching process at operation 304, the substrate supporting surface of the substrate support assembly is maintained at a cryogenic temperature below 0° C. i.e. such as below −20° C., such as below −40° C., such as below-60° C., such as −80° C., while the pressure within the internal volume of chamber body is maintained between 5 mTorr and 300 mTorr.

At operation 306, the exposed portion 207 of the silicon containing layer 204 is exposed to a carbon-free fluorine containing gas. The carbon-free fluorine containing gas converts the exposed portions of the silicon containing layer 204 to reactive portions 210, as illustrated in FIG. 2B. In one or more examples, the carbon-free fluorine containing gas comprises hydrogen fluoride (HF) vapor, xenon difluoride (XeF₂), or iodine heptafluoride (IF₇), or the like.

In one or more examples, the carbon-free fluorine containing gas is flowed into the processing chamber at a flow rate between 50 sccm and 1000 sccm. The carbon-free fluorine containing gas makes contact with the exposed portions 207 of the silicon containing layer 204 through the opening 205 of the masking layer 206. Due to the chemistries of the silicon containing layer 204 and the carbon-free fluorine containing gas, the carbon-free fluorine containing gas is physically absorbed (i.e., undergoes physisorption) by the exposed portion 207 of the silicon containing layer 204. Physisorption converts the exposed portions 207 of the silicon containing layer 204 to reactive portions 210. For example, as depicted in in the film stack 200B of FIG. 2B, the carbon-free fluorine containing gas contacts the exposed portion 207 of the silicon containing layer 204 through opening 205 formed in the masking layer 206 to a reactive portion 210 by physisorption.

In one or more examples, physisorption of the molecules of the carbon-free fluorine containing gas into the exposed portion 207 of the silicon containing layer 204 is self-limiting. Therefore, the reactive portion 210 does not extend the entire depth of the silicon containing layer 204. For example, the reactive portion 210 extends to a reactive portion depth d1 in the silicon containing layer 204. The reactive portion depth d1 is defined from a top surface 208 of the silicon containing layer to a bottom surface 210a of the reactive portion 210. In one or more examples, the reactive portion depth d1 may be controlled based on the time the exposed portion 207 of the silicon containing layer 204 is exposed to the carbon-free fluorine containing gas, the pressure of the carbon-free fluorine containing gas within the internal volume, and the temperature of the substrate.

At operation 308, the reactive portions are removed using a plasma formed from an inert gas. The reactive portions 210 are exposed to the plasma formed from an inert gas through the masking layer 206. Inert gas ions formed in the plasma are directed into contact the reactive portions. The contact from the inert gas ions causes desorption of the reaction portions 210. As depicted by the film stack 200C of FIG. 2C, the reactive portion 210 is etched, resulting in a feature 212. The feature 212 has a feature depth df that is measured from the top surface 208 of the silicon containing layer 204 to a bottom surface 212a of the feature 212. The feature depth df is based on the reactive portion depth d1. For example, in a first etching step the feature depth df is equal to the reactive portion depth d1.

At operation 308, whether the etching process 300 has reached an endpoint is determined. In one example, the endpoint of the etching process 300 is reached when a bottom surface 212a of the feature 212 reaches the top surface of the substrate 202 (i.e., the feature 212 is etched through the entire silicon containing layer 204). The bottom surface 212a of the feature 212 reaching the top surface of the substrate 202 may be determined by checking the processing by-products exiting an exhaust port, such as exhaust port 148 of the etching chamber 102 (FIG. 1). If the material that comprises the substrate 202 is included in the by-products, then the top surface of the substrate (i.e., the endpoint) has been reached. On the other hand, if the material that comprises the substrate is not included in the by-products, then the top surface of the substrate (i.e., the endpoint) has not been reached. Whether the bottom surface 212a of the feature 212 reaches the top surface of the substrate 202 (i.e., the endpoint) can also be determined by measuring the feature depth df using a dedicated measurement tool such as an interferometer. If the feature depth df is equal to the thickness of the silicon containing layer 204, the top surface of the substrate 202 (i.e., the endpoint) has been reached. If the feature depth df is less than the thickness of the silicon containing layer 204, the top surface of the substrate 202 (i.e., the endpoint) has not been reached.

On the other hand, the endpoint is reached when the feature depth df reaches a desired (pre-determined) depth using a dedicated measurement tool such as an interferometer.

If the endpoint has not been reached, the method 300 returns to operation 304 and the silicon containing layer 204 is etched again. On the other hand, if the endpoint has been reached the etching of the silicon containing layer 204 is stopped.

As depicted by the film stack 200D of FIG. 2D, if the endpoint has not been reached, the method 300 returns to operation 306, and the silicon containing layer 204 is re-exposed to the carbon-free fluorine containing gas through the masking layer 206. In one example, the feature 212 is re-exposed to the carbon-free fluorine containing gas. For the reasons described above, the re-exposed portions of the silicon containing layer 204 are converted into a reactive portion 214 having a reactive depth d2. Stated differently, the feature 212 is re-exposed to the carbon-free fluorine containing gas through the masking layer 206. The carbon-free fluorine containing gas fills the feature 212 and forms a reactive portion 214 that extends into the silicon containing layer 204 to a reactive depth d2. Additionally, because the carbon-free fluorine containing gas fills the feature 212, the sidewalls 212b, 212c physically absorb the carbon-free contain gas and are converted into the reactive portion 214.

As depicted by the film stack 200E of FIG. 2E, the method 300 proceeds to operation 308 and the reactive portion 214 is removed using the plasma formed from an inert gas, such as argon (Ar). However, because the silicon containing layer 204 is exposed to the plasma formed from an inert gas through the mask, only the portions of the reactive portion 214 formed on the bottom surface 212a (FIG. 2D) of the feature are removed. Stated differently, the sidewalls 212b, and 212c are not exposed to the directional ions from plasma because they are protected by the masking layer 206. The removal of the reactive portion increases the feature depth df. For example, the feature depth df is now equal to reactive depth d1 plus d2.

As depicted by film stack 200F of FIG. 2F, the silicon containing layer 204 is etched until the endpoint is reached. For example, as shown in FIG. 2E the silicon containing layer 204 is etched (i.e., removed) until bottom surface 212a of the feature 212 reaches the top surface of the substrate 202. Alternatively, the silicon containing layer 204 is etched until the feature depth df is equal to a desired depth.

What is claimed is:

1. A method for forming a feature on a substrate comprising:
exposing a portion of a silicon containing layer formed over the substrate through an opening formed though a masking layer to a carbon-free fluorine containing gas to convert the exposed portion of the silicon containing layer to a reactive portion; and
etching the reactive portion by exposing the reactive portion of the silicon containing layer to a plasma formed from an inert gas.

2. The method of claim 1, wherein the inert gas is argon.

3. The method of claim 1, where the carbon-free fluorine containing gas is hydrogen fluoride (HF).

4. The method of claim 1, wherein the exposing the portion of the silicon containing layer and the etching the reactive portion are cyclically repeated.

5. The method of claim 1, further comprising:
maintaining a substrate support, upon which the substrate is supported, at a temperature below 0° C. while the portion of the silicon containing layer is exposed to the carbon-free fluorine containing gas.

6. The method of claim 1, wherein a pressure of the carbon-free containing gas exposed to the silicon containing layer is between 5 mTorr and 300 mTorr.

7. The method of claim 1, wherein a flow rate of the carbon-free containing gas exposed to the silicon containing layer is between 50 sccm and 1000 sccm.

8. The method of claim 1, wherein the silicon containing layer is fabricated from silicon (Si), silicon nitride (SiN), or silicon oxide (SiO).

9. A method for forming a feature on a substrate comprising:
exposing a portion of a silicon containing layer formed over the substrate through a masking layer formed over the silicon containing layer to hydrogen fluoride (HF) vapor to convert the exposed portion of the silicon containing layer to a reactive portion; and
etching the reactive portion by exposing the reactive portion of the silicon containing layer to a plasma formed from argon (Ar).

10. The method of claim 9, wherein the exposing the portion of the silicon containing layer and the etching the reactive portion are cyclically repeated.

11. The method of claim 9, further comprising:
maintaining a substrate support, upon which the substrate is supported, at a temperature below 0° C. while the portion of the silicon containing layer is exposed to HF vapor.

12. The method of claim 9, wherein a pressure of the HF exposed to the silicon containing layer is between 5 mTorr and 300 mTorr.

13. The method of claim 9, wherein the silicon containing layer is fabricated from silicon (Si), silicon nitride (SiN), or silicon oxide (SiO).

14. A processing chamber comprising:
a controller; and
a memory for storing instructions, which, when executed by the controller, causes the controller to perform a method for forming a feature on a substrate, the method comprising:
exposing a portion of a silicon containing layer formed over the substrate through an opening formed though a masking layer to a carbon-free fluorine containing gas to convert the exposed portion of the silicon containing layer to a reactive portion; and
etching the reactive portion by exposing the reactive portion of the silicon containing layer to a plasma formed from an inert gas.

15. The processing chamber of claim 14, wherein the inert gas is argon.

16. The processing chamber of claim 14, where the carbon-free fluorine containing gas is hydrogen fluoride (HF).

17. The processing chamber of claim 14, wherein the instructions further comprise instructions to cyclically repeat the exposing the portion of the silicon containing layer and the etching the reactive portion.

18. The processing chamber of claim 14, wherein the instructions further comprise instructions to:
maintain a substrate support, upon which the substrate is supported, at a temperature below 0° C. while the portion of the silicon containing layer is exposed to the carbon-free fluorine containing gas.

19. The processing chamber of claim 14, wherein a pressure of the carbon-free fluorine containing gas exposed to the silicon containing layer is between 5 mTorr and 300 mTorr.

20. The processing chamber of claim 14, wherein the silicon containing layer is fabricated from silicon (Si), silicon nitride (SiN), or silicon oxide (SiO).
